(19) United States
(12) Patent Application Publication
(10) Pub. No.: US 2024/0145373 A1
(43) Pub. Date: May 2, 2024

(54) SEMICONDUCTOR PACKAGE

(71) Applicant: Samsung Electronics Co., Ltd., Suwon-si (KR)

(72) Inventor: HYEONGSEOK KANG, Suwon-si (KR)

(21) Appl. No.: 18/332,105

(22) Filed: Jun. 9, 2023

(30) Foreign Application Priority Data
Oct. 31, 2022 (KR) 10-2022-0142809

(51) Int. Cl. H01L 23/498; H01L 23/29; H01L 23/31

(52) U.S. Cl. CPC H01L 23/49838; H01L 23/295; H01L 23/3121; H01L 23/49811; H01L 23/49822; H01L 24/32; H01L 2224/32225

(57) ABSTRACT

Disclosed is a semiconductor package comprising a package substrate, a semiconductor chip on the package substrate, and a mold layer on the package substrate and the semiconductor chip. The package substrate includes a body layer, first conductive patterns and second conductive patterns on the body layer, and a first dielectric layer on the second conductive patterns and at least one of the first conductive patterns. A portion of the mold layer extends into the first dielectric layer and a portion of the second conductive pattern and contacts the body layer.

### CROSS-REFERENCE TO RELATED APPLICATION

This U.S. nonprovisional application claims priority under 35 U.S.C § 119 to Korean Patent Application No. 10-2022-0142809, filed on Oct. 31, 2022 in the Korean Intellectual Property Office, the disclosure of which is hereby incorporated by reference in their entirety.

### BACKGROUND

The present inventive concepts relate to a semiconductor package.

A semiconductor package is provided to implement an integrated circuit chip for use in electronic products. A semiconductor package is typically configured such that a semiconductor chip is mounted on a printed circuit board (PCB) and bonding wires or bumps are used to electrically connect the semiconductor chip to the printed circuit board. With the development of electronic industry, many studies have been conducted to improve reliability and durability of semiconductor packages.

### SUMMARY

Some embodiments of the present inventive concepts provide a semiconductor package with increased reliability.

According to some embodiments of the present inventive concepts, a semiconductor package may comprise: a package substrate; a semiconductor chip on the package substrate; and a mold layer on the package substrate and the semiconductor chip. The package substrate may include: a body layer; first conductive patterns and second conductive patterns on the body layer; and a first dielectric layer on the second conductive patterns and at least one of the first conductive patterns. A portion of the mold layer may extend into the first dielectric layer and a portion of the second conductive patterns and contacts the body layer.

According to some embodiments of the present inventive concepts, a semiconductor package may comprise: a package substrate; a semiconductor chip on the package substrate; and a mold layer on the package substrate and the semiconductor chip. The package substrate may include: a body layer; first conductive patterns and second conductive patterns on the body layer; and a first dielectric layer on the second conductive patterns and at least one of the first conductive patterns. A portion of the mold layer may extend into the first dielectric layer and a portion of the second conductive patterns to and contacts the body layer, and contacts a sidewall of the first dielectric layer and a sidewall of the portion of the second conductive patterns.

According to some embodiments of the present inventive concepts, a semiconductor package may comprise: a package substrate; a semiconductor chip on the package substrate; and a mold layer on the package substrate and the semiconductor chip, wherein the mold layer includes a plurality of filler particles. The package substrate may include: a body layer; first conductive patterns and second conductive patterns on the body layer; a first dielectric layer on the second conductive patterns and at least one of the first conductive patterns; third conductive patterns on a bottom surface of the body layer; and external terminals bonded to the third conductive patterns. A portion of the mold layer may extend into the first dielectric layer and a portion of the second conductive patterns, and contacts the body layer, and may be in a plurality of holes formed in the first dielectric layer and the portion of the second conductive patterns. One or more of the plurality of filler particles may be within each of the plurality of holes. Each of the plurality of holes may have a tetragonal shape, a polygonal shape, or a circular shaped cross section parallel to the package substrate. A width of each of the plurality of holes may be about 2 times to about 4 times a diameter of each of the plurality of filler particle.

### BRIEF DESCRIPTION OF THE DRAWINGS

FIG. 1 illustrates a plan view showing a semiconductor package according to some embodiments of the present inventive concepts.

FIG. 2 illustrates a cross-sectional view taken along line I-I′ of FIG. 1, showing a semiconductor package according to some embodiments of the present inventive concepts.

FIG. 3 illustrates an enlarged view showing section A of FIG. 2.

FIGS. 4A to 4F illustrate cross-sectional views showing a method of fabricating the semiconductor package of FIG. 2.

### DETAILED DESCRIPTION

Some embodiments of the present inventive concepts will now be described in detail with reference to the accompanying drawings to aid in clearly explaining the present inventive concepts.

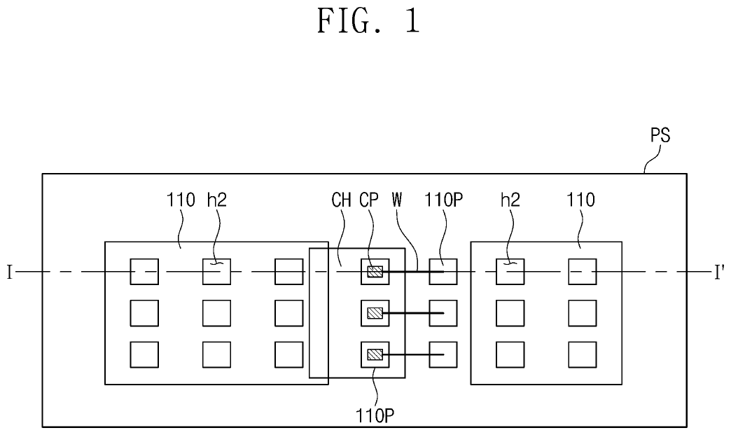

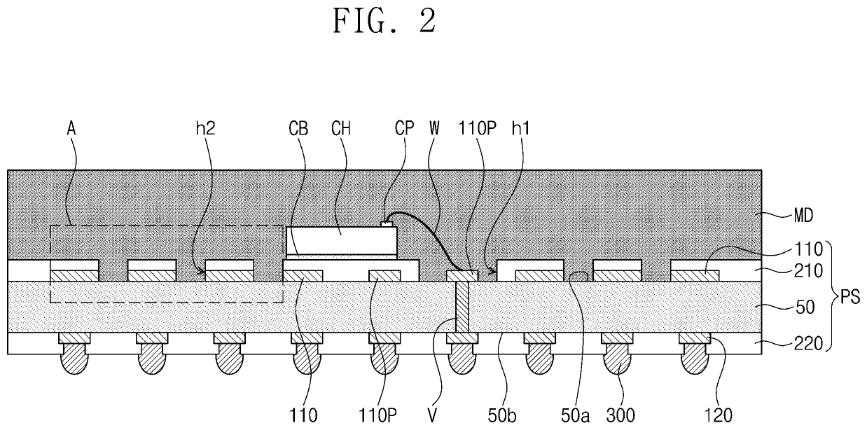

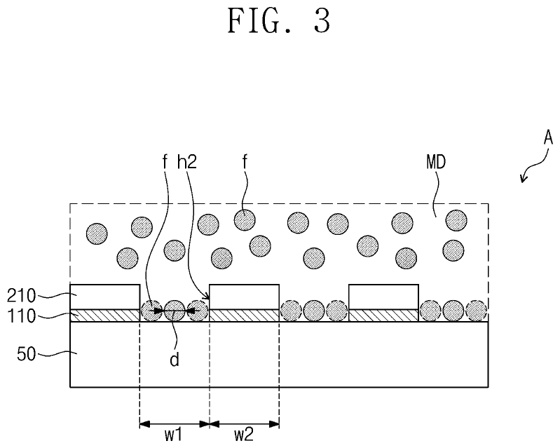

FIG. 1 illustrates a plan view showing a semiconductor package according to some embodiments of the present inventive concepts. FIG. 2 illustrates a cross-sectional view taken along line I-I′ of FIG. 1, showing a semiconductor package according to some embodiments of the present inventive concepts. FIG. 3 illustrates an enlarged view showing section A of FIG. 2.

Referring to FIGS. 1 and 2, a semiconductor package according to the present embodiment may include a package substrate PS, a semiconductor chip CH, and a mold layer MD.

The package substrate PS may include a body layer 50, first conductive patterns 110P, second conductive patterns 110, and third conductive patterns 120.

The body layer 50 may have a top surface 50a and a bottom surface 50b that are opposite to each other. The body layer 50 may include, for example, one or more of a thermosetting resin such as epoxy resin, a thermoplastic resin such as polyimide, a resin in which a thermosetting or thermoplastic resin is impregnated with a reinforcement such as glass fiber and/or inorganic filler (which impregnated resin includes a prepreg or a fire resist-4 (FR4)), and a photosensitive resin, but the present inventive concepts are not limited thereto.

The first conductive patterns 110P and the second conductive patterns 110 may be on the top surface 50a of the body layer 50. The first conductive patterns 110P and the second conductive patterns 110 may be formed of, for example, copper.

The second conductive patterns 110 may have a network shape when viewed in plan view as shown in FIG. 1. That is, the second conductive patterns 110 may have a network shape in the horizonal plane.

A first dielectric layer 210 may be on or cover the second conductive patterns 110 and at least one of the first conductive patterns 110P. The first dielectric layer 210 may include an epoxy-containing layer. The first dielectric layer 210 may be a photosensitive solder resist (PSR) layer.

The first dielectric layer 210 may have a first hole h1 that exposes ones of the first conductive patterns 110P.

A plurality of second holes h2 may be provided in the first dielectric layer 210 and the second conductive patterns 110. The first dielectric layer 210 and the second conductive pattern 110 may have respective sidewalls that are aligned with each other.

The second conductive patterns 110 may have the plurality of second holes h2 that partially expose the body layer 50.

The third conductive patterns 120 may be on the bottom surface 50b of the body layer 50. The third conductive patterns 120 may be formed of, for example, copper.

A second dielectric layer 220 may be on or cover the third conductive patterns 120. An external connection terminal 300 may be bonded to a bottom surface of the second dielectric layer 220. The external connection terminal 300 may be, for example, one or more of conductive bumps, conductive pillars, and solder balls. The external connection terminal 300 may include, for example, at least one material selected from tin and silver. The second dielectric layer 220 may be a photosensitive solder resist (PSR) layer. The second dielectric layer 220 may have a plurality of third holes 220h with which a plurality of external connection terminals 300 are engaged.

A semiconductor chip CH may be mounted on the package substrate PS. The semiconductor chip CH may be attached through an adhesion layer CB onto the first dielectric layer 210.

The semiconductor chip CH may be one selected from a microelectromechanical system (MEMS) chip and a memory chip such as a flash memory chip, a dynamic random access memory (DRAM) chip, a static random access memory (SRAM) chip, an electrically erasable programmable read-only memory (EEPROM) chip, phase change random access memory (PRAM) chip, a magnetic random access memory (MRAM) chip, a resistive random access memory (ReRAM) chip, a high bandwidth memory (HBM) chip, and a hybrid memory cubic (HMC) chip.

The adhesion layer CB may include a non-conductive film (NCF). The adhesion layer CB may be a polymer tape including a dielectric material.

The semiconductor chip CH may include chip pads CP formed on a top surface thereof. The chip pad CP may be connected through a wire W to at least one of the first conductive patterns 110P. The wire W may be formed of a gold (Au) or aluminum (Al) wire.

Although not shown, the semiconductor chip CH may be electrically connected to at least one of the first conductive patterns 110P thereunder.

The semiconductor chip CH may be provided in plural, and the plurality of semiconductor chips CH may be vertically stacked or horizontally on the package substrate PS.

A via V may be formed below at least one of the first conductive patterns 110P that is connected to the chip pad CP of the semiconductor chip CH. A top end of the via V may be connected to the first conductive pattern 110P, and a bottom end of the via V may be connected to at least one of the third conductive patterns 120. The via V, the first conductive pattern 110P, and the third conductive pattern 120 may be integrally connected into a single unitary piece. The via V may be a metal pillar, and may include a conductive material including at least one material selected from copper (Cu), gold (Au), silver (Ag), nickel (Ni), tungsten (W), aluminum (Al), and a combination thereof. The first conductive pattern 110P may be supplied with a signal voltage, and the second conductive pattern 110 may be supplied with a ground voltage or a power voltage. When the second conductive pattern 110 is supplied with a ground voltage, the second conductive pattern 110 may serve as an electromagnetic interference (EMI) shield. As a result, it may be possible to provide a semiconductor package whose signal noise is reduced and reliability is increased.

The mold layer MD may be on or cover the package substrate PS and the semiconductor chip CH. The mold layer MD may be on or cover the first dielectric layer 210, the first conductive patterns 110P, and the second conductive patterns 110. The mold layer MD may be on or cover the plurality of first holes h1.

For example, a portion of the mold layer MD may penetrate or extend into the first dielectric layer 210 and the second conductive patterns 110 to come into contact with the body layer 50. In this case, the mold layer MD may be in contact with both the sidewall of the first dielectric layer 210 and the sidewall of the second conductive pattern 110.

An adhesive force between the body layer 50 and the mold layer MD may be greater than an adhesive force between the first dielectric layer 210 and the mold layer MD.

The mold layer MD may include an epoxy molding compound. The body layer 50 and the mold layer MD may have the same or similar physical properties. Thus, there may be an increase in adhesive force between the body layer 50 and the mold layer MD.

As a portion of the mold layer MD penetrates or extends into the first dielectric layer 210 and the second conductive patterns 110 to come into contact with the body layer 50, It may be possible to prevent delamination between the body layer 50 and the mold layer MD.

Referring to FIG. 3 the mold layer MD may include a plurality of filler particles f. The plurality of filler particles f may include silica. The plurality of filler particles f may cause the mold layer MD to have increased insulation and mechanical strength. The filler particles may have a circular cross section.

Ones of the filler particles f of the mold layer MD may be positioned within each of the second holes h2. In this case, each of the second holes h2 may have a tetragonal shape, a polygonal shape, or a circular shape when viewed in plan; that is, each of the second holes h2 may have a tetragonal, a polygonal, or a circular shaped cross section taken parallel to the package substrate PS. The second holes h2 may have any other various shapes. Each of the second holes h2 may have a width w1 that is about 2 times to 4 times a diameter d of the filler particle f.

The second holes h2 may be formed to have an interval w2 the same as the width w1 of each of the second holes h2. The present inventive concepts, however, are not limited thereto, and the second holes h2 may be formed to have an interval w2 different from the width w1 of each of the second holes h2.

When the second holes h2 are formed to have an interval w2 the same as the width w1 of each of the second holes h2, the interval w2 between the second holes h2 may be about 2 times to 4 times the diameter d of the filler particle f. For example, the width w1 of each of the second holes h2 may be about 3 times the diameter d of the filler particle f, and as shown in FIG. 3, three filter particles f may be within each of the second holes h2.

Others of the filler particles f of the mold layer MD may be distributed (e.g., uniformly distributed) on the first dielectric layer 210. The filler particles f distributed on the first dielectric layer 210 may have a density the same as that of the filler particles f positioned within each of the second holes h2.

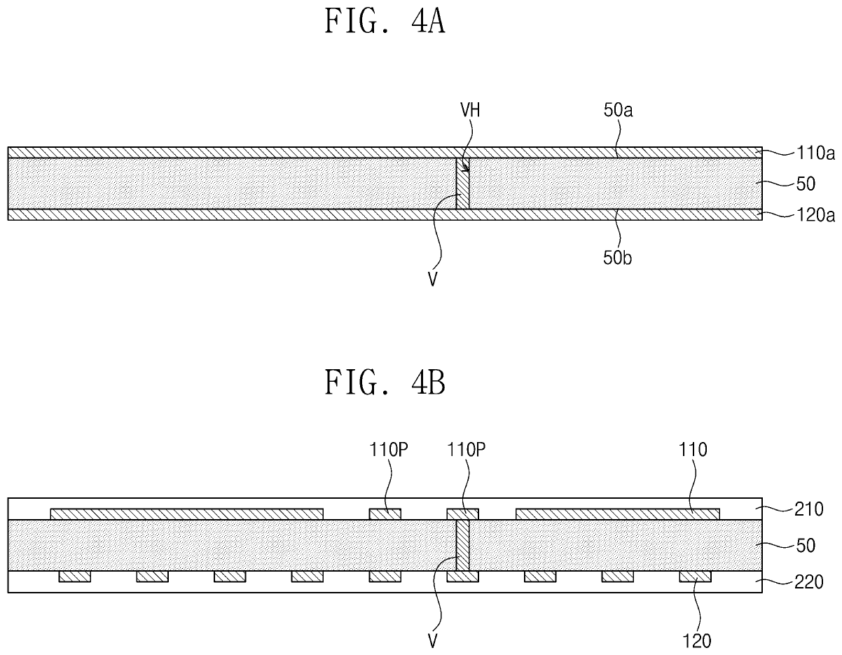

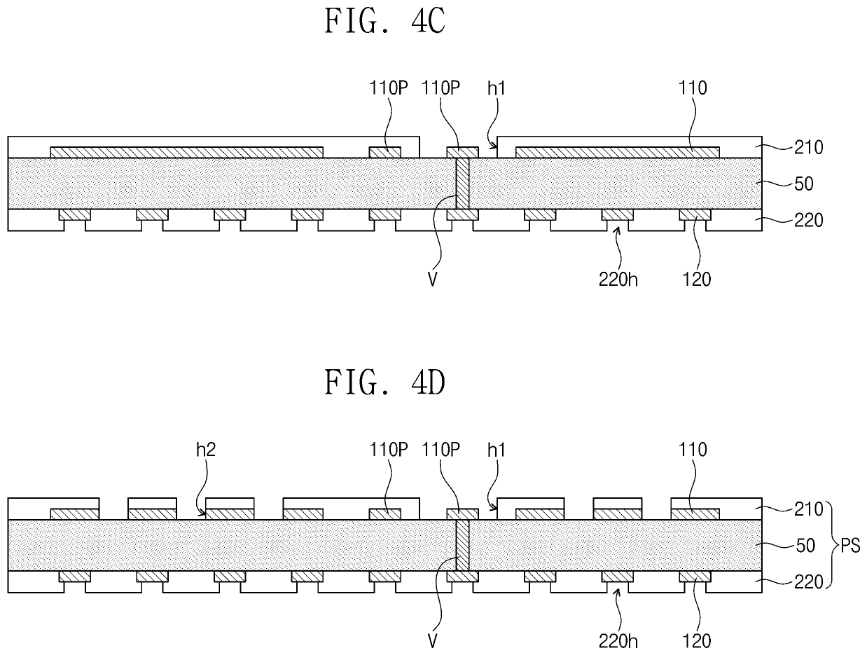

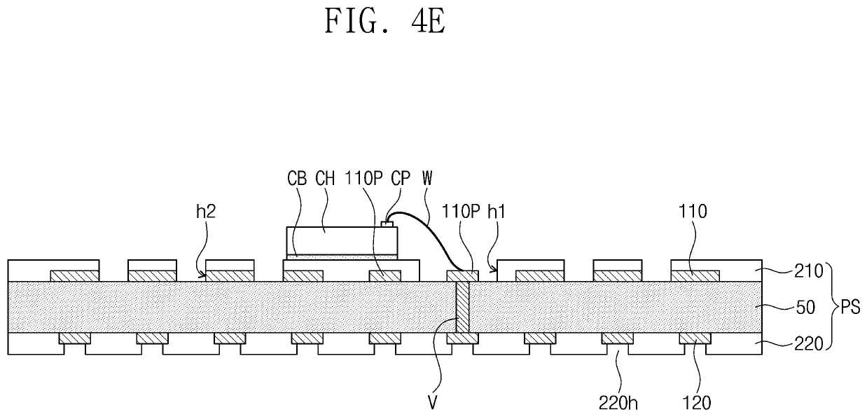

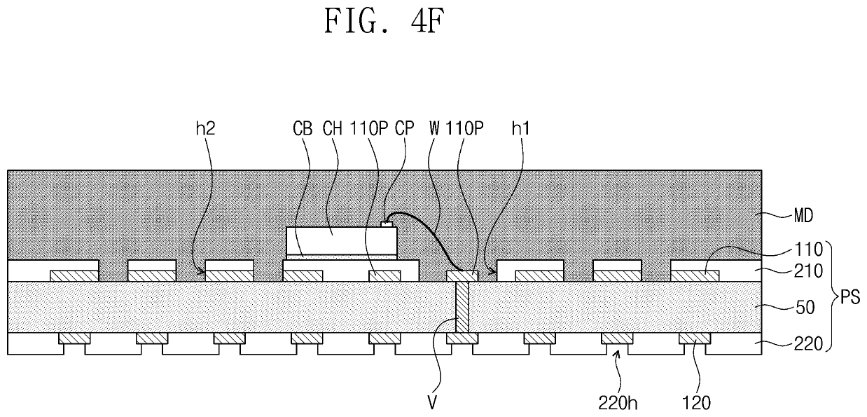

FIGS. 4A to 4F illustrate cross-sectional views showing a method of fabricating the semiconductor package of FIG. 1.

Referring to FIG. 4, a via hole VH may be formed to penetrate or extend into a body layer 50.

The body layer 50 may have a top surface 50a and a bottom surface 50b that are opposite to each other. The body layer 50 may include, for example, one or more of a thermosetting resin such as epoxy resin, a thermoplastic resin such as polyimide, a resin in which a thermosetting or thermoplastic resin is impregnated with a reinforcement such as glass fiber and/or inorganic filler (which impregnated resin includes a prepreg or a fire resist-4 (FR4)), and a photosensitive resin, but the present inventive concepts are not limited thereto.

A seed layer may be conformally formed in the via hole VH and on the top and bottom surfaces 50a and 50b of the body layer 50, and then a plating process may be performed to form a first conductive layer 110a, a via V, and a second conductive layer 120a. The first conductive layer 110a may be formed on the top surface 50a of the body layer 50, and the second conductive layer 120a may be formed on the bottom surface 50b of the body layer 50. The first conductive layer 110a and the second conductive layer 120a may include at least one material selected from copper, nickel, and gold.

Referring to FIG. 4B, the first conductive layer 110a may be etched to form first conductive patterns 110P and second conductive patterns 110, and the second conductive layer 120a may be etched to form third conductive patterns 120. The first conductive pattern 110P may be supplied with a signal voltage, and the second conductive pattern 110 may be supplied with a ground voltage or a power voltage. When the second conductive pattern 110 is supplied with a ground voltage, the second conductive pattern 110 may serve as an electromagnetic interference (EMI) shield.

Afterwards, a first dielectric layer 210 may be formed on (e.g., to cover) the first conductive patterns 110P and the second conductive patterns 110, and a second dielectric layer 220 may be formed on (e.g., to cover) the third conductive patterns 120. The first dielectric layer 210 and the second dielectric layer 220 may be formed by coating and baking processes. In this case, the first dielectric layer 210 and the second dielectric layer 220 may each be a photosensitive solder resist (PSR) layer.

Referring to FIG. 4C, exposure and development processes may be performed such that a portion of the first dielectric layer 210 may be removed to form a first hole h1 that exposes one or more of the first conductive patterns 110P. In addition, an exposure process may be performed such that a portion of the second dielectric layer 220 may be removed to form a plurality of third holes 220h in the second dielectric layer 220. For example, the first dielectric layer 210 may have the first hole h1 that is formed to expose one or more of the first conductive patterns 110P, and the second dielectric layer 220 may have the third holes 220h that are formed to partially expose a bottom surface of the second dielectric layer 220.

As shown in figures, the exposed first conductive pattern 110P may be connected through the via V to one of the third conductive patterns 120. A top end of the via V may be connected to the first conductive pattern 110P, and a bottom end of the via V may be connected to at least one of the third conductive patterns 120. The via V, the first conductive pattern 110P, and the third conductive pattern 120 may be integrally connected into a single unitary piece. The via V may be a metal pillar, and may include a conductive material including at least one material selected from copper (Cu), gold (Au), silver (Ag), nickel (Ni), tungsten (W), aluminum (Al), and a combination thereof.

Referring to FIG. 4D, an etching process may be employed to simultaneously and partially remove the first dielectric layer 210 and the second conductive patterns 110, and thus a plurality of second holes h2 may be formed in the first dielectric layer 210 and the second conductive patterns 110. For example, the plurality of second holes h2 may be formed in the first dielectric layer 210 and the second conductive patterns 110. Therefore, the first dielectric layer 210 and the second conductive pattern 110 may have their sidewalls that are aligned with each other. The second holes h2 may expose a portion of the body layer 50, and thus a subsequently described mold layer MD may be attached to the exposed portions of the body layer 50.

Ones of the plurality of second holes h2 may be positioned at a regular interval. For example, the plurality of second holes h2 may be spaced apart by a uniform distance. Although it is illustrated that the first dielectric layer 210 and the second conductive patterns 110 are partially removed to allow the second hole h2 to have a bottom end located at the same level as that of a bottom end of the first hole h1, the first dielectric layer 210 and the second conductive patterns 110 may be partially removed to have their relatively large depths to allow the second hole h2 to have a bottom end located at a lower level than that of a bottom end of the first hole h1.

A package substrate PS may be eventually formed.

Referring to FIG. 4E, an adhesion layer CB may be used to bond a semiconductor chip CH onto the first dielectric layer 210. The semiconductor chip CH may be one selected from a microelectromechanical system (MEMS) chip and a memory chip such as a flash memory chip, a dynamic random access memory (DRAM) chip, a static random access memory (SRAM) chip, an electrically erasable programmable read-only memory (EEPROM) chip, phase change random access memory (PRAM) chip, a magnetic random access memory (MRAM) chip, a resistive random access memory (ReRAM) chip, a high bandwidth memory (HBM) chip, and hybrid memory cubic (HMC) chip.

A wire W may be used to connect a chip pad CP of the semiconductor chip CH to one of the first conductive patterns 110P. The wire W may be formed of a gold (Au) or aluminum (Al) wire.

Referring to FIG. 4F, a mold layer MD may be formed on (e.g., to cover) the body layer 50, the first dielectric layer 210, and the exposed first conductive pattern 110P. A portion of the mold layer MD may penetrate or extend into the first dielectric layer 210 and the second conductive patterns 110 to come into contact with the body layer 50. In this case, the mold layer MD may be in contact with both the sidewall of the first dielectric layer 210 and the sidewall of the second conductive pattern 110. As such, the mold layer MD may be attached to the body layer 50. An adhesive force between the body layer 50 and the mold layer MD may be greater than an adhesive force between the first dielectric layer 210 and the mold layer MD.

For example, the mold layer MD may include an epoxy molding compound. The body layer 50 and the mold layer MD may have the same or similar physical properties. Thus, there may be an increase in adhesive force between the body layer 50 and the mold layer MD.

The mold layer MD may include a plurality of filler particles f. The plurality of filler particles f may include silica. The plurality of filler particles f may cause the mold layer MD to have increased insulation and mechanical strength.

Ones of the filler particles f of the mold layer MD may be positioned within each of the second holes h2. In this case, each of the second holes h2 may have a tetragonal shape, a polygonal shape, or a circular shape when viewed in plan; that is, each of the second holes h2 may have a tetragonal, a polygonal, or a circular shaped cross section taken parallel to the package substrate PS. The second holes h2 may have any other various shapes. Each of the second holes h2 may have a width w1 that is about 2 times to 4 times a diameter d of the filler particle f.

The second holes h2 may be formed to have an interval w2 the same as the width w1 of each of the second holes h2. The present inventive concepts, however, are not limited thereto, and the second holes h2 may be formed to have an interval w2 different from the width w1 of each of the second holes h2.

When the second holes h2 are formed to have an interval w2 the same as the width w1 of each of the second holes h2, the interval w2 between the second holes h2 may be about 2 times to 4 times the diameter d of the filler particle f.

Other portions of the filler particles f of the mold layer MD may be distributed (e.g., uniformly distributed) on the first dielectric layer 210. The filler particles f distributed on the first dielectric layer 210 may have a density the same as that of the filler particles f positioned within each of the second holes h2.

Referring back to FIG. 2, external connection terminals 300 may be bonded to the bottom surface of the second dielectric layer 220. A sawing or singulation process may be performed to cut the mold layer MD and the package substrate PS, thereby fabricating an individual semiconductor package. Accordingly, a semiconductor package of FIG. 2 may be finally manufactured.

A semiconductor package according to some embodiments of the present inventive concepts may be configured such that a mold layer is in contact with a body layer of a package substrate, with the result that delamination may be prevented, solved, minimized, or alleviated between the mold layer and a dielectric layer. As a result, a semiconductor package may increase in reliability.

Although the present inventive concepts have been described in connection with some embodiments of the present inventive concepts illustrated in the accompanying drawings, it will be understood to those skilled in the art that various changes and modifications may be made without departing from the technical spirit and essential feature of the present inventive concepts.

What is claimed is:

1. A semiconductor package, comprising:
a package substrate;
a semiconductor chip on the package substrate; and
a mold layer on the package substrate and the semiconductor chip,
wherein the package substrate includes:
a body layer;
first conductive patterns and second conductive patterns on the body layer; and
a first dielectric layer on the second conductive patterns and at least one of the first conductive patterns,
wherein a portion of the mold layer extends into the first dielectric layer and a portion of the second conductive patterns and contacts the body layer.

2. The semiconductor package of claim 1, wherein an adhesive force between the body layer and the mold layer is greater than an adhesive force between the first dielectric layer and the mold layer.

3. The semiconductor package of claim 1, wherein
the body layer includes a prepreg, and
the mold layer includes an epoxy molding compound.

4. The semiconductor package of claim 3, further comprising a plurality of filler particles in the mold layer.

5. The semiconductor package of claim 4, wherein
a portion of the mold layer is in each of a plurality of holes formed in the first dielectric layer and the portion of the second conductive patterns, and
one or more of the plurality of filler particles are within each of the plurality of holes.

6. The semiconductor package of claim 5, wherein
each of the plurality of holes has a tetragonal, a polygonal, or a circular shaped cross section parallel to the package substrate, and
a width of each of the plurality of holes is about 2 times to about 4 times a diameter of each of the plurality of filler particles.

7. The semiconductor package of claim 6, wherein a space between each of the plurality of holes is the same as the width of each of the plurality of the holes.

8. The semiconductor package of claim 1, wherein the mold layer contacts a sidewall of the first dielectric layer and a sidewall of the portion of the second conductive patterns.

9. The semiconductor package of claim 5, wherein some of the plurality of filler particles are distributed on the first dielectric layer.

10. The semiconductor package of claim 1, wherein
the first conductive patterns are supplied with a signal voltage, and
the second conductive patterns are supplied with a ground voltage or a power voltage.

11. The semiconductor package of claim 1, wherein the second conductive patterns have a network shape in a horizontal plane.

12. A semiconductor package, comprising:
a package substrate;
a semiconductor chip on the package substrate; and
a mold layer on the package substrate and the semiconductor chip,
wherein the package substrate includes:
a body layer;
first conductive patterns and second conductive patterns on the body layer; and
a first dielectric layer on the second conductive patterns and at least one of the first conductive patterns,
wherein a portion of the mold layer:
extends into the first dielectric layer and a portion of the second conductive patterns and contacts the body layer, and
contacts a sidewall of the first dielectric layer and a sidewall of the portion of the second conductive patterns.

13. The semiconductor package of claim 12, wherein an adhesive force between the body layer and the mold layer is greater than an adhesive force between the first dielectric layer and the mold layer.

14. The semiconductor package of claim 12, wherein
the body layer includes a prepreg, and
the mold layer includes an epoxy molding compound.

15. The semiconductor package of claim 14, further comprising a plurality of filler particles.

16. The semiconductor package of claim 15, wherein
the portion of the mold layer is in each of a plurality of holes formed in the first dielectric layer and the portion of the second conductive patterns, and
one or more of the plurality of filler particles are within each of the holes.

17. The semiconductor package of claim 16, wherein
each of the holes has a tetragonal, a polygonal, or a circular shaped cross section parallel to the package substrate, and
a width of each of the holes is about 2 times to about 4 times a diameter of ones of the plurality of filler particles.

18. The semiconductor package of claim 16, wherein an interval between the holes is the same as a width of each of the holes.

19. The semiconductor package of claim 12, wherein the second conductive patterns have a network shape in a horizontal plane.

20. A semiconductor package, comprising:
a package substrate;
a semiconductor chip on the package substrate; and
a mold layer on the package substrate and the semiconductor chip, wherein the mold layer includes a plurality of filler particles,
wherein the package substrate includes:
a body layer;
first conductive patterns and second conductive patterns on the body layer;
a first dielectric layer that covers the second conductive patterns and at least one of the first conductive patterns;
third conductive patterns on a bottom surface of the body layer; and
external terminals bonded to the third conductive patterns,
wherein a portion of the mold layer or extends into the first dielectric layer and a portion of the second conductive patterns and contacts the body layer and is in a plurality of holes formed in the first dielectric layer and the portion of the second conductive patterns,
wherein one or more of the plurality of filler particles are within each of the holes, and
wherein each of the plurality of holes has a tetragonal, a polygonal, or a circular shaped cross section parallel to the package substrate, and
wherein a width of each of the plurality of holes is about 2 times to about 4 times a diameter of each of the plurality of filler particles.
